(19) United States
(12) Patent Application Publication
(10) Pub. No.: US 2007/0237335 A1
(43) Pub. Date: Oct. 11, 2007

(54) Hormonic inversion of room impulse response signals

(75) Inventor: Elizabeth A. O'Sullivan, Belfast (GB)

Correspondence Address: DTS, INC., 5171 CLARETON DRIVE, AGOURA HILLS, CA, 91301, US

(73) Assignee: Queen's University of Belfast

(21) Appl. No.: 11/401,547

(22) Filed: Apr. 11, 2006

(51) Int. Cl. H03G 3/00; G10H 1/02

(52) U.S. Cl. 381/63; 381/61; 84/630

(57) ABSTRACT

A method and apparatus models with a digital computer the impulse response characteristics of an acoustic system (“room” for convenience), based upon a measured impulse response signal from the acoustic system. The steps of the method include: processing the measured impulse response signal by band-limited decimation in at least one band to obtain a band-limited, decimated signal (BLD signal); calculating with a digital computer, based on said BLD signal, a model impulse response of a rational polynomial form; and finding poles and zeros of said rational polynomial. In a preferred embodiment, the rational polynomial form is further simplified by removing a set of pole/zero pairs that meet a specified set of pair criteria.

### BACKGROUND OF THE INVENTION

1. Field of the Invention

The invention relates to audio signal processing generally, and more specifically to the characterization, simulation, and compensation of room acoustics by characterizing Room Impulse Response (RIR) of an acoustic environment.

2. Description of the Related Art

Recording and reproduction of audio signals continues to be complicated by room acoustics. Although reproduction and recording apparatus have reached extremely high levels of fidelity (in relation to psychoacoustic capabilities of the listener), characterization of the room environment continues to be an “Achilles heel” of the Audio recording or listening process. Every recording session occurs in a unique, often poorly characterized audio environment (“room”); every listening experience takes place in another, often very different, listening environment. Nevertheless, popular audio techniques such as surround-sound audio systems attempt to reproduce a sound field that is faithful to, or predictably modified from, the recording environment. The knowledge and proper modeling of RIR is also valuable for applications other than consumer audio: for example, the characterization of RIR is valuable for echo cancellation (for example, for automobile cell phones or conference phones) or for indirect estimation of physical parameters (such as room dimensions).

Techniques are known for measuring the “room impulse response” (RIR) of an acoustic environment (which need not be an actual “room”). In theory, every acoustic environment could be well characterized by measuring its associated RIR. However, in practice, measured RIRs with adequate data are extremely complex. Measuring such RIRs adequately is difficult; inversion or deconvolution with such complex functions is even more challenging. Some attempts simplify the problem by considering only steady state response (disregarding all important transient response). This approach is not entirely successful, although some acoustic environments can be improved by equalizing the steady state response.

Prior methods have used typically Fourier transform techniques as well as time domain techniques to measure and characterize room impulse response. RIRs represented by time domain or Fourier transform techniques are extremely complex, limiting the use of such representations to applications where high cost and low speed do not prohibit their use.

Parametric signal processing can offer substantial benefits as compared with FFT based spectral estimators. For example, an RIR time signal can be modeled as a linear combination of decaying complex exponentials. For a digitized signal {cₙ} with sample rate τ(t=nτ, n=0 . . . N−1) we have:

$$Eq . 1 \text{:}$$

$${c}_{n} = {\sum }_{k = 1}^{K} ⅆ {kⅇ}^{- {ⅈω}_{k} nτ}$$

Where {ωₖ,dₖ} are the complex frequency and complex amplitude of each kth harmonic respectively. Harmonic inversion corresponds to decomposing a time signal into its respective components {K,ωₖ,dₖ}. When a signal is successfully inverted we are able to obtain the position [symbol] (ωₖ), width ℑ(ωₖ), height (|dₖ|), and phase (Arg(dₖ)) of each resonant structure in the spectrum and as such, the signal is fully reconstructable. For this to be possible we must have N≧2K.

Such a task is challenging as inversion of exponentially decaying sinusoids is numerically ill-conditioned, arising from the fact that it is a highly nonlinear interpolation problem. For lengthy signals encountered in practice this usually amounts to rooting high order polynomials. Inversion of RIR signals is further hindered by the fact that we do not have a priori knowledge of the order K. For these reasons, parametric signal processing has not been conventional for the analysis of RIR signals.

### SUMMARY OF THE INVENTION

A method in accordance with the invention models with a digital computer the impulse response characteristics of an acoustic system (“room” for convenience), based upon a measured impulse response signal from the acoustic system. The steps of the method include: processing the measured impulse response signal by band-limited decimation in at least one band to obtain a band-limited, decimated signal (BLD signal); calculating with a digital computer, based on said BLD signal, a model impulse response of a rational polynomial form; and finding poles and zeros of said rational polynomial. In a preferred embodiment, the rational polynomial form is further simplified by removing a set of pole/zero pairs that meet a specified set of pair criteria.

According to another aspect, the invention includes a method of conditioning an electronic signal representative of an audio signal to simulate the effect of an acoustic environment on the audio signal. The method includes convolving the signal with a digital model of a room impulse response, wherein said digital model is calculated by: measuring a room impulse response to obtain a measured room impulse response signal; calculating from the room impulse response signal a model impulse response of a rational polynomial form; and calculating the rational polynomial coefficients by the method of Padé approximants.

According to another aspect, the invention includes a method of conditioning an electronic signal representative of an audio signal in an acoustic environment, to compensate for an effect of the acoustic environment on the audio signal. The method includes the steps of: measuring the impulse response of the acoustic environment to obtain a measured impulse response; processing the measured impulse response signal by band-limited decimation (BLD) to obtain a band-limited, decimated signal (BLD signal); calculating with a computer a model impulse response of a rational polynomial form; finding poles and zeros of the polynomial form; reducing the order of the model impulse response by removing pole/zero pairs that meet a specifiet set of pair criteria; calculating an inverse model impulse response from the simplified impulse response model; and conditioning the electronic signal by convolving it with the model inverse impulse response.

According to another aspect, the invention includes an apparatus for conditioning an electronic signal representative of an audio signal, to simulate the effect of an acoustic environment on said signal. The apparatus includes a data storage device storing room impulse response data; a harmonic inversion core engine, programmed to calculated a modeled impulse response based upon room impulse response data stored by said data storage device, by calculating a polynomial model of the room impulse response data by a method of Padé approximants; and an acoustic convolution filter engine, arranged to receive the electronic signal and to convolve the signal with the modeled room impulse response, producing a conditioned audio output signal.

According to another aspect, the invention includes a method of estimating physical characteristics of an acoustic system, based upon a measured impulse response signal of the acoustic system. The method includes the steps of: processing the measured impulse response signal by band-limited decimation (BLD) to obtain a Band-limited, decimated signal (BLD signal); calculating, based on the BLD signal, a model impulse response of a polynomial form; finding poles and zeros of said polynomial; reducing the order of the model impulse response by removing a set of pole/zero pairs that meet a specified set of pair criteria, to obtain a simplified model impulse response; and estimating the room dimensions based upons poles of said simplified model impulse response.

According to another aspect, the invention includes an apparatus for modeling the acoustic response characteristics of an acoustic system, based on a measured impulse response of the acoustic system. The apparatus includes: a signal processor, arranged to receive the measured impulse response and process the response by band-limited decimation (BLD) to obtain a band-limited, decimated signal (BLD signal); a harmonic inversion core engine arranged to receive the BLD signal from the signal processor, and programmed to calculate a model impulse response in the form of a Padé approximant function.

### BRIEF DESCRIPTION OF THE DRAWINGS

The present invention is generally shown by way of reference to the accompanying drawings in which:

FIG. 1 is a block diagram of an apparatus in accordance with the invention, together with and in context of an acoustic environment and associated measuring apparatus;

FIGS. 2a and 2b are a flow diagram in two parts, illustrating steps of a method in accordance with the invention;

FIG. 3a is a graph of amplitude vs. frequency for an example room impulse response (RIR) as measured;

FIG. 3b is a graph of amplitude vs. frequency for a simplified RIR modeled by a decimated, band limited Padé approximant, modeled after the measured response in FIG. 3a;

FIG. 3c is a graph of amplitude vs. frequency for a further simplified modeled RIR, reduced from the function of FIG. 3b by removal of selected pole/zero pairs (“Froissart doublets”); and

FIG. 4 is a graph of an apparatus in accordance with another aspect of the invention, suitable for conditioning an audio signal by a modeled RIR or inverse modeled RIR.

### DETAILED DESCRIPTION OF THE INVENTION

General Aspects

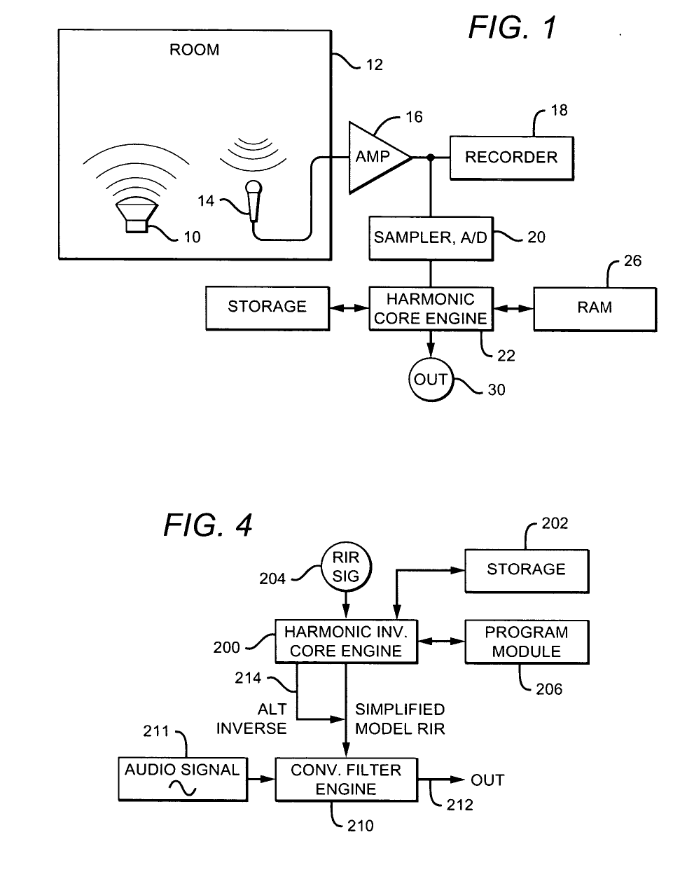

FIG. 1 shows in very general form an apparatus in accordance with the invention, together and in context of an acoustic environment and associated measuring apparatus. The acoustic environment is and measuring apparatus are shown to clarify and illustrate the operation of the apparatus and associated methods (discussed below). It should be understood that in some embodiments the invention may not require certain elements, such as microphones, shown in FIG. 1; the invention may also act upon pre-recorded and stored signal, for example, whether audio or electronic, digital or analog (with appropriate conversion).

To obtain a room impulse response (RIR) signal, an acoustic system (“room”) is first excited by an audio signal transducer (such as a speaker). Note that the acoustic system need not be a literal “room”, but could be an indoor or outdoor environment, a mechanical, or even an electromechanical system, dynamic or static. We use the terminology “room” and “RIR” to simplify understanding by tying the discussion to a common listening experience. No limitation is intended by this terminology.

Various conventional signal and analytical methods can be used to record the RIR from the room. For example, the excitation can be a frequency swept signal or “chirp”. Alternatively, a time domain response to a impulse-like signal (“pop”) can be recorded. Other methods including noise methods are known in the art. The result is either a time-domain or a frequency domain response signal, depending on the method of acquisition. The excitation signal is emitted by speaker 10 and reverberates in the room 12. Microphones or other transducers 14 respond to the reverberation, converting it into an electronic signal. The signal is then amplified by amplifier 16 and optionally recorded by recorder 18 on a recording medium (either in analog or digitized form).

The original or recorded RIR, if analog, is then sampled digitized (if the signal is acquired or recorded digitally this may be omitted) by sampler and A/D converter 20. Optionally, additional signal pre-processing may be applied. The sampled and converted signal is then input to an harmonic inversion core engine 22 for processing in accordance with the method of the invention, discussed below. The harmonic inversion core engine calculates a simplified transfer function that approximates the measured RIR. Preferably, a storage device 24 communicates with the harmonic inversion core engine 22 to store one or more simplified transfer functions.

In a preferred embodiment, the harmonic inversion core engine 22 may be a digital computer in concert with a program module executable on the digital computer to calculate simplified transfer functions based on the measured RIR by the methods described below. Suitable random access memory (RAM) 26 should also be provided, in communication with the digital computer, to enable the calculation and storage input, output, and intermediate results. As output 30 the core engine 22 produces either recorded or real time representation of the simplified transfer function, which is a simplified model of the RIR.

Methods of the Invention

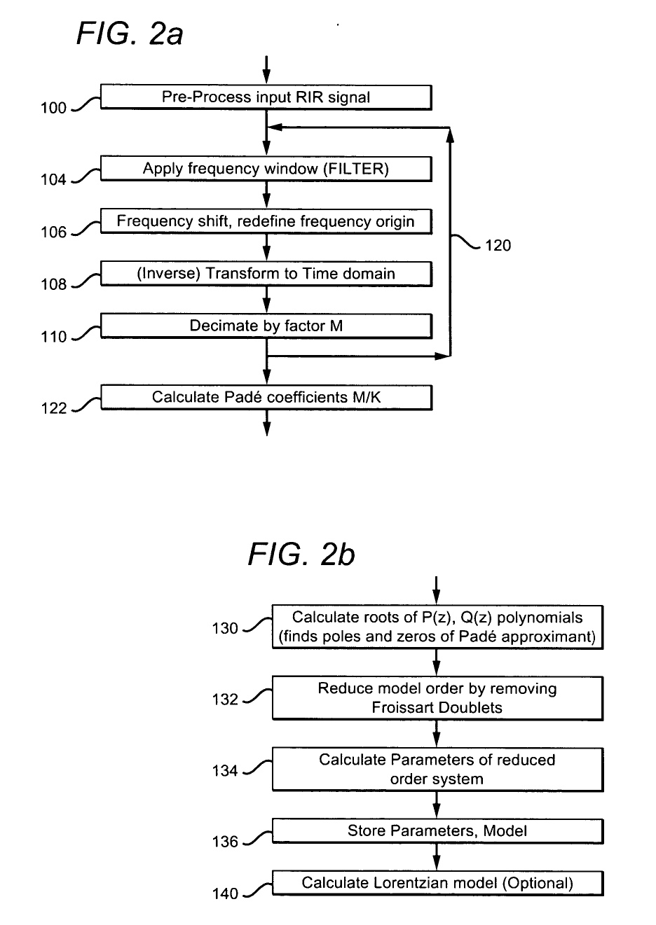

A method in accordance with the invention is diagrammed generally in FIG. 2. An input RIR signal is optionally pre-processed to produce an processed input RIR signal (step 100). The input RIR signal may be from a stored database, directly measured, or otherwise obtained. Preferably, the input RIR signal is transformed into a frequency domain representation, suitably by a Fast Fourier Transform (FFT) or similar technique. A sub-band window is then selected in windowing step 104, and the signal is shifted in frequency to redefine the frequency origin (step 106). Specifically, in one suitable windowing technique a window kε[kₘᵢₙ,kₘₐₓ] of length N_{d}=Kₘₐₓ−Kₘᵢₙ+1 is selected and the values outside this window are set to zero. The window is then frequency shifted to relocate the band limited spectrum around the origin. The new signal is then transformed by an inverse transform, back to a time domain representation (step 108). The signal is then decimated (step 110) by a factor M_{d} (every M_{d}^{th} sample is selected, the intervening samples discarded) to yield a complex, band limited, decimated (BLD) signal. The process of decimation is known in audio signal processing, being employed, for example, in the art of subband coding for signal compression.

The method as illustrated contemplates transformation into a frequency domain representation, followed by frequency windowing and inverse transformation back to time domain. However, alternate methods might advantageously be employed for forming the BLD signal, including digital filtering (subband filtering) followed by decimation. The use of multi-band digital filter banks followed by decimation in the subbands can efficiently yield one or more complex, band limited and decimated signals (BLD signals). Methods of efficient digital subband filtering are discussed, for example, in P. P. Vaidyanathan, Multirate Systems and Filter Banks, Prentice Hall (New Jersey, 1993).

Empirically, it has been found that window sizes should preferably be restricted to around 200 samples or less. The frequency domain windowing technique deletes those samples outside of the window (which are zero). Therefore, within each window there is no loss of information. In practice, care should be taken around the window edges; when these coincide with resonant spectral structures, errors can occur.

Optionally, the method includes a procedure (represented by path 120) to reiterate the windowing, band limiting, inverse transformation, and decimation step in another subband, to obtain a further BLD signal representing the RIR in another subband of interest. If the iterative option is employed, two or more of the BLD signals may be reintegrated to obtain a windowed RIR signal. Otherwise, the BLD signal represents a widowed RIR signal for further processing.

Based on the windowed BLD signal, the harmonic inversion engine next calculates M/K Padé coefficients (step 128). We assume that the RIR can be represented by a unique rational approximation of the form:

$$Eq . 2 \text{:} \\ [ M \text{/} K ] f ( z ) = \frac{{\sum }_{j = 0}^{M} {P}_{j} {z}^{j}}{{\sum }_{j = 0}^{K} {q}_{j} {z}^{j}} = \frac{{P}_{M} ( z )}{{Q}_{K} ( z )}$$

(The “Padé Approximant)
where P_{M}(z) is a polynomial of degree at most M, and Q_{K}(Z) is a polynomial of degree at most K. Note that z is a complex variable, corresponding to e^{-iω}^{ₖ}^{nτ} in equation 1. We use the form of Padé that imposes the normalization condition Q_{K}(0)=1, which can be achieved, without loss of generality, by choosing q₀=1. the remaining coefficients are chosen such that the power series of the approximant matches the power series of the function being approximated up to the degree M+K (inclusive). The Padé coefficients are then calculated (by a digital computer, in the invention) using the equations:

$$Eq . 3 \text{:}$$

$${\sum }_{j = 0}^{K} {q}_{j} {c}_{n - j} = {p}_{n} for n = 0 … M$$

$$Eq . 4 \text{:}$$

$${\sum }_{j = 0}^{K} {q}_{j} {c}_{n - j} = 0 for n = M + 1 … M + K .$$

where if n<j, cₙ₋ⱼ=0. Eq.(4) provides the denominator coefficients, which are substituted into Eq. 3 to calculate the numerator coefficients. The Decimated Padé Approximation process uses the diagonal approximants (M=K) and off-diagonal approximants (M=K+1 or M=K−1), respectively.

The poles Q_{K}(zₖ), zₖ=exp(−iωₖτ_{d}), k=1 . . . K, give the complex frequencies {ωₖ}.

$$Eq . 5 \text{:}$$

$${ω}_{k} = \frac{ⅈ}{{τ}_{d}} ln ( {z}_{k} )$$

where ln(zₖ)=ln|zₖ|iArg(zₖ). The complex amplitudes {dₖ} can be found using Cauchy's residue formula,

$$Eq . 6 \text{:}$$

$${d}_{k} = \frac{{P}_{k} ( {z}_{k} )}{{Q}_{K}^{′} ( {z}_{k} )} or {d}_{k} = \frac{{P}_{K} ( {z}_{k} )}{{z}_{k} {Q}_{K}^{′} ( {z}_{k} )}$$

for the input series

$${\sum }_{n = 0}^{∞} {z}^{- ( n - 1 )} and {\sum }_{n = 0}^{∞} {z}^{- n}$$

respectively.

Next, in step 130 the method calculates the roots of numerator and denominator polynomials P(z) and Q(z), thus finding the poles and zeros of the Padé approximant. This can be accomplished by numerical methods. For example, when rooting polynomials of high order it is found to be robust to use eigenvalue techniques that exploit the structure of a companion matrix. An algorithm for one such eigenvalue procedure is detailed, for example, in Chapter 9.5 of Press, W. H. Teukolsy, S. A., Vetterling, W. T. and Flannery, B. P., Numerical Recipes 2^{nd} Edition, (Cambridge University Press, 1992). The extension to complex numbers is straightforward.

Based on power series analysis, Padé approximants are known accelerators of slowly converging series and can extrapolate the RIR signal (Eq. 1) beyond its region of convergence. As such, the DPA signal processor has the power to achieve higher resolution compared to an FFT technique using the same input data.

In the preferred embodiment, we next (step 132) reduce the model Order {K} by removing certain pole/zero pairs (“Froissart Doublets”) that meet a specified set of pair criteria, to obtain a simplified impulse response model. With all parametric signal processors it is prudent to combine processing with some form of noise reduction; otherwise these techniques can produce unphysical artifacts. Padé approximants are interesting as they offer different approaches to quantifying the order of the system, thus removing these undesirable features. For example, Froissart doublets, characterized by pole-zero near-cancellation within a Padé approximant, can often be removed as an efficient means of noise reduction.

In a particular variation of the invention, a simple technique is employed for the removal of Froissart doublets. Having computed the maximum Padé approximant for a BLD signal, we define the neighborhood of a pole zₚ as:
(The open disc): D(zₚ;ε):={zεC:≡z−zₚ|<ε}
Where C denotes the complex plane.

Froissart Doublets are then defined, for our practical purpose, as any zero zₛ lying in the neighborhood of a pole, such that:
|zₚ−zₛ|<ε Eq. 7
where we require that there is only one zero and one pole in any pair within the approximant. As we deal only with one approximant per window, this technique is very efficient. Optionally, a computational procedure may be used whereby ε is chosen automatically via the use of error analysis.

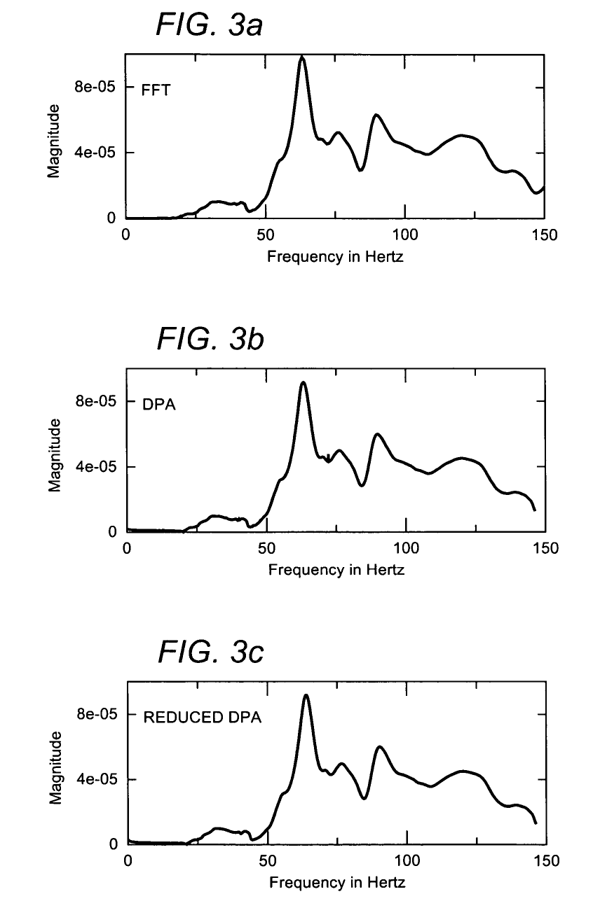

As an example, FIG. 3a shows the first 150 Hz of the spectrum of an experimental RIR taken from a room. FIG. 3b shows the Decimated, Padé approximant model of the RIR. In the DPA spectrum one can see a noticable spike at around 73 Hz that does not appear in the original RIR signal. The signal of FIG. 3b is processed by removing Froissart doublets, setting ε for this purpose at 1.0×10⁻³. in Eq. 7. After removal we find K=37 frequency parameters are retained. The reconstructed signal with these remaining parameters is shown in FIG. 3c. Note that the spurious spike at 73 Hz has been removed with virtually no degradation in the spectrum. It has been found that a tolerance level for ε of 1.0×10⁻³ is sufficient in reducing the windowed RIR signals to similar orders, with minimal degradation to the spectrum.

After reducing the order of the model by removing Froissart doublets, the parameters of the reduced system are calculated (step 134). The simplified, reduced order Padé approximant includes all the information required to reconstruct a model RIR signal in time domain (by Eq. 1, above). The model can then be stored for later use or output for further use (step 136). Optionally, in optional step 140 the reduced-order Padé model may be used to calculate a Lorentzian model of the form:

$$Eq . 8 \text{:}$$

$$F ( ω ) = ⅈ {\sum }_{k = 1}^{K} \frac{{ⅆ}_{k}}{ω - ( {ω}_{0} + {ω}_{k} )}$$

Where dₖ and ωₖ are easily calculated by the equations previously given. This corresponds (in a frequency domain representation) to finding the parameters for the parametric form of Eq. 1, above. The Lorentzian form is often useful because the parameters can often be related to physical characteristics of the acoustic system which evoked the RIR. For example, the frequency of a dominant pole of the system can be related easily to a room dimension such as length. More specifically, a box-like chamber of length L is known to exhibit a room resonance pole at frequency f=c/2L where c is the velocity of sound in the acoustic medium, suitably estimated at 343 m/s for typical conditions.

Based on the Lorentzian model, in some embodiments an optional step 142 may be performed to estimate physical characteristics of the acoustic system that produced the measured or stored RIR. Additional assumptions or constraints may be used in this step, based on the knowledge available of the system. In practice, dual or multiple measurements of the RIR may be compared to determine those poles that consistently appear in the room response. Such poles may be reasonably assumed to result from physical characteristics of the system rather than noise.

Application to Signal Conditioning

FIG. 4 shows in general form an apparatus using the above described technique in an application to condition a signal by a modeled RIR response. A harmonic inversion core engine 200 is coupled to receive data from either a data storage device 202, or an acoustic signal input 204. The harmonic inversion core engine 200 or controlled by an executable module 206 to calculate a simplified, modeled impulse response from stored room impulse response data by calculating a polynomial model of said room impulse response data by a method of Padé approximants. Preferably, the method discussed above in connection with FIG. 2 is used, employing band limiting and decimation to simplify the signal, and removal of pole/zero pairs to further simplify the model RIR. An acoustic convolution filter engine 210 is coupled to receive an input electronic signal at a first input and further coupled to said harmonic inversion core engine 200 to receive the simplified, modeled RIR at a second input. Said convolution filter engine 210 is arranged to convolve said input electronic signal with said modeled room impulse response, producing a conditioned audio output signal at output 212.

In another variation, it may be desired to condition an audio signal with an inverse RIR to compensate for measured effects of an acoustic environment. The arrangement of FIG. 4 can be used, provided that provision is made to invert the simplified, modeled RIR before inputting it into the convolution filter engine 210. Accordingly, alternate signal path 212 is shown coupling an optional inverse RIR from an output 214 of the harmonic inversion core engine 200 to the convolution filter engine 210.

It should be noted that the signal conditioning could be performed by various means in the convolution filter engine 210. It is known in the art that convolution can be performed (often more easily) in the frequency domain. Accordingly, some or all of the signals in FIG. 4 could be presented, conditioned, or converted by transform techniques to a transform representation (such as by an FFT, Discrete Cosine transform, or other known techniques). Accordingly, the signal conditioning shown in FIG. 4 could be in either time domain or transform domain; outputs could be provided in either or both forms as the application demands.

While the invention has been described in detail with regards to several embodiments, it should be appreciated that various modifications and/or variations may be made in the invention without departing from the scope or spirit of the invention. In this regard it is important to note that practicing the invention is not limited to the applications described herein above. Many other applications and/or alterations may be utilized provided that such other applications and/or alterations do not depart from the intended purpose of the invention.

I claim:

1. A method for modeling with a digital computer the impulse response characteristics of an acoustic system (“room”), based upon a measured impulse response signal from the acoustic system, comprising the steps of:
Processing said measured impulse response signal by band-limited decimation in at least one band to obtain a Band-limited, decimated signal (BLD signal);
Calculating with a digital computer, based on said BLD signal, a model impulse response of the polynomial form,
$$[ M \text{/} K ] f ( z ) = \frac{{\sum }_{j = 0}^{M} {p}_{j} {z}^{j}}{{\sum }_{j = 0}^{K} {q}_{j} {z}^{j}} = \frac{{P}_{M} ( z )}{{Q}_{K} ( z )}$$
where P_{M}(z) is a polynomial of degree at most M, and Q_{K}(z) is a polynomial of degree at most K, and z is a complex variable; and
With a digital computer, finding poles and zeros of said polynomial.

2. The method of claim 1, wherein said calculating step further comprises: reducing the order of the model impulse response by removing a set of pole/zero pairs that meet a specified set of pair criteria, to obtain a simplified impulse response model.

3. The method of claim 2, wherein said set of pair criteria includes a requirement that selected pole/zero pairs having pole-zero separation in the complex plane that is less than a predetermined absolute value.

4. The method of claim 3, further comprising further simplifying said model impulse response by removing poles having negative real components.

5. The method of claim 1, wherein said processing of said impulse response signal comprises transforming said impulse response signal into a frequency domain representation and windowing said impulse response signal in the frequency domain.

6. The method of claim 1, wherein said step of processing said measured impulse response signal comprises:
filtering said impulse response signal with a digital filter to separate said impulse response signal into subband signals; and
decimating said subband signals.

7. A method of conditioning an electronic signal representative of an audio signal to simulate the effect of an acoustic environment on said signal, comprising the steps of:
Convolving the signal with a digital model of a room impulse response, by processing with a digital computer;
Wherein said digital model is calculated by:
Measuring a room impulse response to obtain a measured room impulse response signal;
Calculating from said room impulse response signal a model impulse response of the polynomial form:
$$[ M \text{/} K ] f ( z ) = \frac{{\sum }_{j = 0}^{M} {p}_{j} {z}^{j}}{{\sum }_{j = 0}^{K} {q}_{j} {z}^{j}} = \frac{{P}_{M} ( z )}{{Q}_{K} ( z )}$$
where P_{M}(z) is a polynomial of degree at most M, and Q_{K}(z) is a polynomial of degree at most K, and z is a complex variable; and
Wherein said coefficients M and K are calculated by the method of Padé approximants.

8. The method of claim 7, wherein said calculating step further comprises:
With a digital computer, finding poles and zeros of said model impulse response; and
Reducing the order of the model impulse response by removing a set of pole/zero pairs that meet a specified set of pair criteria, to obtain a simplified impulse response model.

9. The method of claim 8, wherein said calculating step further comprises:
Processing said measured impulse response signal by band-limited decimation (BLD) to obtain a Band-limited, decimated signal (BLD signal); and
Calculating said model response of the polynomial form from the BLD signal.

10. The method of claim 8, wherein said set of pair criteria includes a requirement that selected pole/zero pairs have pole-zero separation in the complex plane that is less than a predetermined absolute value.

11. A method of conditioning an electronic signal representative of an audio signal in an acoustic environment, to compensate for an effect of an acoustic environment on said audio signal, comprising the steps of:
Measuring the impulse response of the acoustic environment to obtain a measured impulse response;
Processing said measured impulse response signal by band-limited decimation (BLD) to obtain a Band-limited, decimated signal (BLD signal);
Calculating with a digital computer, based on said BLD signal, a model impulse response of the polynomial form:
$$[ M / K ] f ( z ) = \frac{{\sum }_{j = 0}^{M} {p}_{j} {z}^{j}}{{\sum }_{j = 0}^{K} {q}_{j} {z}^{j}} = \frac{{P}_{M} ( z )}{{Q}_{K} ( z )}$$
where P_{M}(z) is a polynomial of degree at most M, and Q_{K}(Z) is a polynomial of degree at most K, and z is a complex variable;
With a digital computer, finding poles and zeros of said polynomial; and
Reducing the order of the model impulse response by removing a set of pole/zero pairs that meet a specified set of pair criteria, to obtain a simplified impulse response model.
Calculating an inverse model impulse response from said simplified impulse response model, to obtain a model inverse impulse response;
Conditioning the electronic signal by convolving said electronic signal with said model inverse impulse response, thereby producing a conditioned signal compensated for the effects of the acoustic environment.

12. An apparatus for conditioning an electronic signal representative of an audio signal, to simulate the effect of an acoustic environment on said signal, comprising:
A data storage device storing room impulse response data;
A harmonic inversion core engine, programmed to calculate a modeled impulse response based upon room impulse response data stored by said data storage device, by calculating a polynomial model of said room impulse response data by a method of Padé approximants; and
An acoustic convolution filter engine, coupled to receive the electronic signal and arranged to convolve said signal with said modeled room impulse response, producing a conditioned audio output signal.

13. The apparatus of claim 12, further comprising:
A signal processing module, arranged to receive said room impulse response data from said data storage device and to pre-process said room impulse response data by band limited decimation, producing a band limited, decimated RIR signal.

14. The apparatus of claim 13, wherein said signal processing module comprises a digital filter and decimator.

15. The apparatus of claim 13, wherein said signal processing module comprises a processor that transforms said room impulse response data into a frequency domain representation, then performs windowing and decimation in the frequency domain.

16. The apparatus of claim 13, further comprising:
A program module, executable on said harmonic inversion core engine, arranged to reduce the model order of said polynomial model by removing pole/zero pairs having pole-zero separation in the complex plane that is less than a predetermined absolute value.

17. A method of estimating physical characteristics of an acoustic system, based upon a measured impulse response signal of the acoustic system, comprising the steps of:
Processing said measured impulse response signal by band-limited decimation (BLD) to obtain a Band-limited, decimated signal (BLD signal);
Calculating with a digital computer, based on said BLD signal, a model impulse response of the polynomial form,
$$[ M / K ] f ( z ) = \frac{{\sum }_{j = 0}^{M} {p}_{j} {z}^{j}}{{\sum }_{j = 0}^{K} {q}_{j} {z}^{j}} = \frac{{P}_{M} ( z )}{{Q}_{K} ( z )}$$
where P_{M}(z) is a polynomial of degree at most M, and Q_{K}(z) is a polynomial of degree at most K, and z is a complex variable;
With a digital computer, finding poles and zeros of said polynomial;
Reducing the order of the model impulse response by removing a set of pole/zero pairs that meet a specified set of pair criteria, to obtain a simplified model impulse response; and
Estimating the room dimensions based upon poles of said simplified model impulse response.

18. An apparatus for modeling the acoustic response characteristics of an acoustic system, based on a measured impulse response of the acoustic system, comprising:
A signal processor, arranged to receive the measured impulse response and to process said response by band-limited decimation (BLD) to obtain a Band-limited, decimated signal (BLD signal); and
A harmonic inversion core engine arranged to receive said BLD signal from said signal processor and programmed to calculate from said BLD signal a model impulse response in the form of a Padé approximant function, by calculating a polynomial model of said room impulse response data by a method of Padé approximants.

19. The apparatus of claim 18, wherein said harmonic inversion core engine is further programmed to simplify said model impulse response by removal of pole/zero pairs that meet a specified set of pair criteria.

20. The apparatus of claim 19, wherein said specified set of pair criteria includes a requirement that pole/zero pairs selected must have pole-zero separation in the complex plane that is less than a predetermined absolute value.

21. The apparatus of claim 18 wherein said harmonic inversion core engine comprises:
A programmable digital computer;
random access memory in communication with said digital computer;
a program module, executable on said digital computer, said program module comprising instructions for calculating the model impulse response in the form of a Padé approximant function by a method of Padé approximants.

22. The apparatus of claim 21, wherein said signal processor comprises a digital computer.
